(19) United States
(12) Patent Application Publication
(10) Pub. No.: US 2015/0287808 A1
(43) Pub. Date: Oct. 8, 2015

(54) SEMICONDUCTOR STRUCTURE AND METHOD FOR MANUFACTURING THE SAME

(71) Applicant: INSTITUTE OF MICROELECTRONICS, CHINESE ACADEMY OF SCIENCES, Beijing (CN)

(72) Inventors: Haizhou Yin, Poughkeepsie, NY (US); Wei Jiang, Fujian (CN); Huilong Zhu, Poughkeepsie, NY (US)

(21) Appl. No.: 14/435,616

(22) PCT Filed: Oct. 25, 2012
(86) PCT No.: PCT/CN2012/083478

§ 371 Date: Apr. 14, 2015

(30) Foreign Application Priority Data
Oct. 18, 2012 (CN) 201210397791.7

(51) Int. Cl. H01L 29/66; H01L 21/306; H01L 29/08; H01L 29/16; H01L 29/04; H01L 29/78; H01L 21/02; H01L 29/06

(52) U.S. Cl. CPC H01L 29/66636; H01L 29/66651; H01L 29/6656; H01L 21/02532; H01L 21/02592; H01L 21/02667; H01L 21/30604; H01L 21/30625; H01L 29/0649; H01L 29/16; H01L 29/04; H01L 29/78; H01L 29/0847

(57) ABSTRACT

A method for manufacturing a semiconductor structure is disclosed. The method comprises: providing an SOI substrate (200) comprising, from bottom to top, a base layer (201), a buried insulator layer (202), and a surface active layer (203); forming a gate stack on the substrate; removing the surface active layer (203) on both sides of the gate stack and removing a part of the buried insulator layer (202) to form an opening (240); filling the opening (240) with semiconductor materials so as to form source/drain regions (250). Correspondingly, a semiconductor structure is also disclosed. In the present disclosure, by extending the source/drain region to the buried insulator layer of the substrate, the source/drain series resistance is reduced while not increasing parasitic capacitance between the gate and the source/drain regions.

### CROSS-REFERENCE TO RELATED APPLICATION

This application claims priority to the Chinese Patent Application No. 201210397791.7, filed on Oct. 18, 2012, entitled “Semiconductor Structure and Method for Manufacturing the same”, which is incorporated herein by reference in its entirety.

### TECHNICAL FIELD

The present disclosure relates to the field of semiconductor manufacturing, and in particular, to a semiconductor structure and method for Manufacturing the same.

### BACKGROUND OF THE INVENTION

Reducing the source/drain junction depth is one of the effective solutions to suppress short channel effects and punch-through effects, and to improve threshold characteristics. MOSFET short channel effects and punch-through effects can be improved by a small source/drain junction depth, and better subthreshold characteristics can be achieved. The substrate of UTBSOI devices is an ultra-thin SOI layer, which may have good control over source/drain dopant diffusion and form shallow junctions. But smaller source/drain junction depth will cause the source/drain series resistance to increase, hence decreasing the output current and transconductance of the device, and reducing the driving capability and speed of the device and its circuits. Furthermore, shallow source/drain junctions may also affect reliability of source/drain contacts. To suppress the short channel effects and avoid source/drain punch-through, and to gain better subthreshold characteristics, the source/drain junction depth is required to be as small as possible, whereas to improve the transconductance and speed, the source/drain junction depth is required to be as large as possible. This is one contradictory situation that needs to be resolved in small size MOSFET devices. The way to resolve this issue is adoption of raised source/drain structure.

MOSFETs having raised source/drain may have reduced source/drain series resistance and better device characteristics. However, raised source/drains of MOSFETs may reduce the distance between the gate and the source/drain, resulting in the increase of parasitic capacitance between the gate electrode and the source/drain. FIG. 1 is a cross-sectional view of an raised source/drain MOSFET, wherein the upper surface of the source/drain region 130 is higher than the lower surface of the gate stack.

### SUMMARY OF THE DISCLOSURE

The present disclosure provides a semiconductor structure and method for manufacturing the same to solve the problem of increased parasitic capacitance caused by raised source/drain MOSFET, wherein the source/drain region is extended to the buried insulator layer of the substrate, so that the source/drain series resistance is decreased while not increasing parasitic capacitance between the gate electrode and the source/drain.

According to one aspect of the present invention, the present disclosure provides a method for manufacturing a semiconductor structure comprising the following steps:
a) Providing an SOI substrate comprising, from bottom to top, a base layer, a buried insulator layer, and a surface active layer;
b) Forming a gate stack on the substrate;
c) Removing the surface active layer on both sides of the gate stack and a part of the buried insulator layer to form an opening; and
d) Filling the opening with semiconductor materials so as to form a source/drain region.

According to another aspect of the present invention, the present disclosure provides a semiconductor structure comprising an SOI substrate, a gate stack and a source/drain region, wherein:

The SOI substrate comprises, from bottom to top, a base layer, a buried insulator layer, and a surface active layer;

The gate stack is located on the surface active layer; and

The source/drain region is located on both sides of the gate stack, and is extended to the buried insulator layer.

In the present disclosure, since the source/drain region extends to the buried insulator layer of the substrate, the source/drain series resistance is reduced while not increasing the parasitic capacitance between the gate and the source/drain.

### BRIEF DESCRIPTION OF THE DRAWINGS

By detailed description of non-limiting embodiments with reference to the attached drawings, the above mentioned and/or other additional features, objectives and advantages of the present disclosure will become more apparent:

FIG. 1 is a cross-sectional view of an raised source/drain MOSFET in the prior art;

FIG. 2 is a flowchart of a method for manufacturing a semiconductor according to the present disclosure;

FIG. 3 to FIG. 8 are cross-sectional views of the semiconductor structure in various steps of its manufacturing process following the method illustrated in FIG. 2.

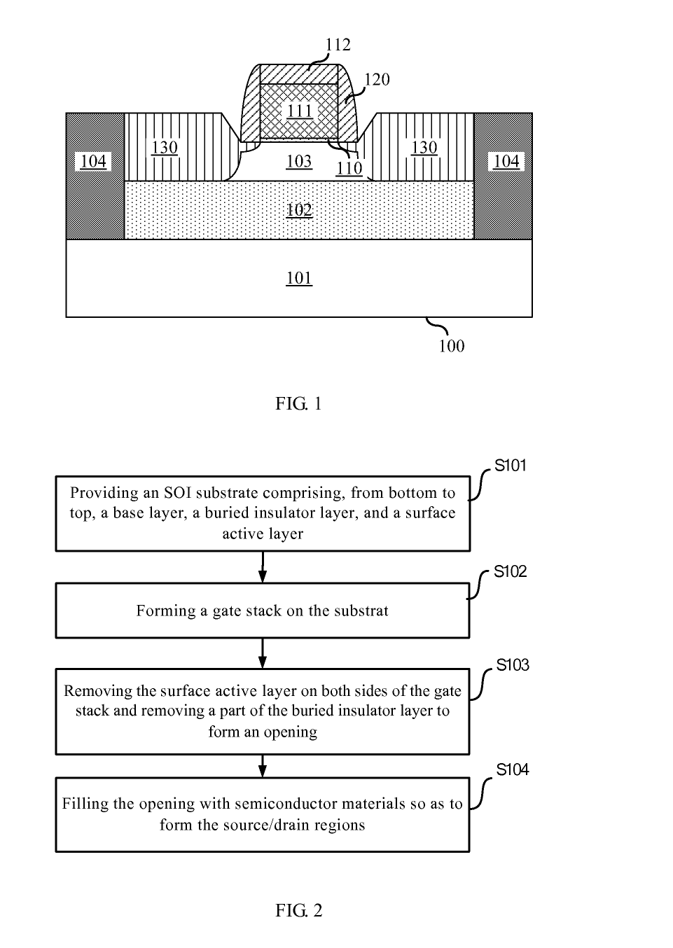

The same or similar reference numbers in attached drawings represent the same or similar parts.

### DETAILED DESCRIPTION

The embodiment of the present disclosure will be described in detail. The example of the embodiment is presented in the attached drawings. The embodiment described below by reference to the drawings is exemplary for explaining the present disclosure, and cannot be considered as limiting the present disclosure.

The following disclosure provides many different embodiments or examples to achieve different structures of the present invention. In order to simplify the disclosure of the present invention, the components and settings of a set of specific examples will be described herein. Certainly, they are only examples, and are not to limit the present invention. In addition, reference numerals and/or letters may be repeated in different examples in the present disclosure. This repetition is only for simplification and clarity, and does not indicate any relationship between various embodiments and/or settings discussed. In addition, the present disclosure provides various examples of specific processes and materials, but those skilled in the art may appreciate the application and applicability of other processes and/or materials. It should be noted that the components shown in the attached drawings are not necessarily drawn to scale. Descriptions of well-known components and processing techniques may be omitted in the present disclosure to avoid unnecessarily limiting the present disclosure.

In the following, a method for forming a semiconductor structure shown in FIG. 2 will be described in detail with reference to FIG. 3 to FIG. 8.

Referring to FIG. 2 and FIG. 3, in step S101, an SOI substrate 200 is provided, and the SOI substrate 200 comprises, from bottom to top, a base layer 201, a buried insulator layer 202, and a surface active layer 203.

In the exemplary embodiment, the base layer 201 is monocrystalline silicon. In other exemplary embodiments, the base layer 201 can also comprise other basic semiconductors, such as germanium. Alternatively, the base layer 201 can also comprise compound semiconductors, such as silicon carbide, gallium arsenide, indium arsenide or indium phosphide. Typically, the depth of the base layer 201 can be, but not limited to, about several hundred micrometers, such as in a depth range of about 0.1 mm-1.5 mm.

The buried insulator layer 202 can be silicon oxide, silicon nitride, or any other suitable insulator materials. Typically, the depth of the buried insulation layer 202 can be in the range of about 100 nm-300 nm.

The surface active layer 203 can be any one of the semiconducting materials comprised in the base layer 201. In the exemplary embodiment, the surface active layer 203 is monocrystalline silicon. In other exemplary embodiments, the surface active layer 203 can also comprise other basic semiconductors or compound semiconductors. According to design requirements in prior art (such as a P-type or N-type substrate), the surface active layer 203 can comprise all kinds of doping configurations. The doping type for the surface active layer 203 is P-type for NMOS and N-type for PMOS with a doping concentration of about 10¹⁵−10¹⁸ cm⁻³. Typically, the depth of the surface active layer 203 is about 10 nm-100 nm.

Specifically, in step S101, the method further comprises forming an isolation region 204 in the substrate, such as shallow trench isolation (STI) structure, to electrically isolate semiconducting devices. The shallow trench isolation (STI) structure penetrates the surface active layer 203 and connects with the buried insulator layer 202. Alternatively, the STI structure may penetrates the buried insulator layer 202.

Referring to FIG. 2 and FIG. 3, in step S102, a gate stack is formed on the substrate. The gate stack comprises a gate dielectric layer 210 and a gate 211. Optionally, the gate stack can also comprise a cap layer 212 covering the gate 211 formed by, for example, depositing silicon nitride, silicon oxide, silicon oxynitride, silicon carbide, or combinations thereof to protect the top region of the gate 211 from being damaged in subsequent processes. The gate dielectric layer 210 is located above the surface active region 203 on the substrate. It can be of high K dielectrics, such as one or any combinations of HfO₂, HfSiO, HfSiON, HfTaO, HfTiO, HfZrO, Al₂O₃, La₂O₃, ZrO₂ and LaAlO. In another exemplary embodiment, it can also be thermal oxide layer, comprising silicon oxide, silicon nitride; the depth of the gate dielectric layer 210 can be 1 nm-10 nm, such as 5 nm or 8 nm. The gate 211 is formed subsequently on the gate dielectric layer 210, for example, by depositing heavily doped polycrystalline silicon, or by firstly forming a work function metal layer (such as TaC, TiN, TaTbN, TaErN, TaYbN, TaSiN, HfSiN, MoSiN, RuTaₓ, NiTaₓ for MONS, and MoNₓ, TiSiN, TiCN, TaAlC, TiAlN, TaN, PtSiₓ, Ni₃Si, Pt, Ru, Ir, Mo, HfRu, RuOₓ for PMOS) with a depth of about 1 nm-20 nm, such as 3 nm, 5 nm, 8 nm, 10 nm, 12 nm, or 15 nm, and then forming a heavily doped polycrystalline Si, Ti, Co, Ni, Al, W, or their alloy on the work function metal layer.

In some other exemplary embodiments according to the present disclosure, a gate last process can also be performed to form the gate stack comprising a gate 211 (a dummy gate in this case) and a gate dielectric layer 210 under the gate 211. The gate 211 (a dummy gate in this case) is formed with a depth of about 10 nm-80 nm by depositing polycrystalline silicon, polycrystalline SiGe, amorphous silicon, doped or undoped silicon oxide, silicon nitride, silicon oxynitride, silicon carbide, or even metals on the gate dielectric layer 210. Optionally, a cap layer may also be formed on the gate 211 (a dummy gate in this case) such as by depositing silicon nitride, silicon oxide, silicon oxynitride, silicon carbide, or combinations thereof to protect the top region of the dummy gate 211 from being damaged in reaction with the depositing metal layer in the subsequent contact layer formation process. In another gate last process exemplary embodiment, the gate dielectric layer 210 may be formed after the dummy gate is removed and before the work function metal layer is filled in subsequent processes.

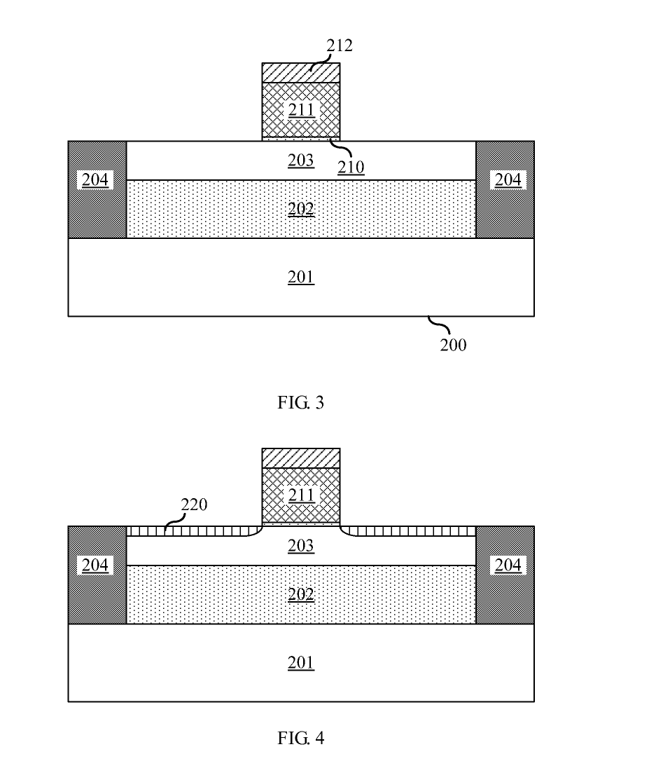

Optionally, as illustrated in FIG. 4, after the gate stack is formed, a source/drain extension region 220 may be formed on both sides of the gate stack with the gate stack as mask to implant P-type or N-type dopants or impurities in the surface active layer 203. The source/drain extension region 220 can be P-type doped Si for PMOS or N-type doped Si for NMOS. The semiconducting structure is then annealed to activate the impurities in the source/drain region 220, for example, by rapid thermal annealing, spike annealing, or other suitable methods.

Subsequently, spacers may be formed on sidewalls of the gate stack. As illustrated in FIG. 5, spacers 230 can be formed on sidewalls of the gate stack to isolate the gate stack. The spacers 230 can be silicon nitride, silicon oxide, silicon oxynitride, silicon carbide, or combinations thereof, and/or other suitable materials. The spacers 230 can be of multi-layer structure. The spacers 230 can be formed by deposition-etching process with a depth range of about 10 nm-100 nm, such as 30 nm, 50 nm, or 80 nm.

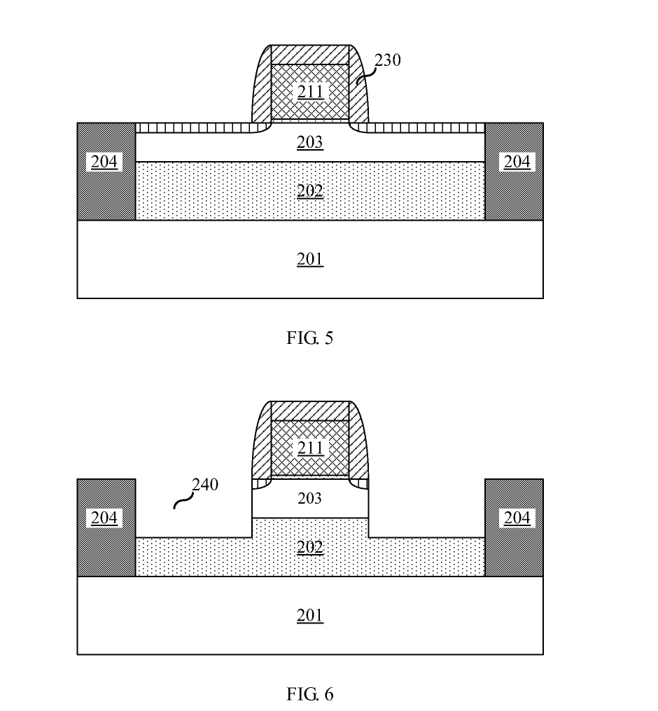

Referring to FIG. 2 and FIG. 6, in step S103, the surface active layer 203 and part of the buried insulator layer 202 on both sides of the gate stack are removed to form an opening 240. In the exemplary embodiment, the surface active layer 203 is etched, then the buried insulator layer 202 is etched, and the etching stops at the buried insulator layer 202. The surface active layer 203 and the buried insulator layer is anisotropically etched with the gate stack as mask by dry etching such as plasma etching. The etching gases in the dry etching process may comprise carbon hydrides such as sulfur hexafluoride (SF₆), hydrogen bromide (HBr), iodide, hydrogen (HI), chlorine, argon, helium, methane (and chlorinated methane), acetylene, ethylene, or combinations thereof, and/or other suitable materials.

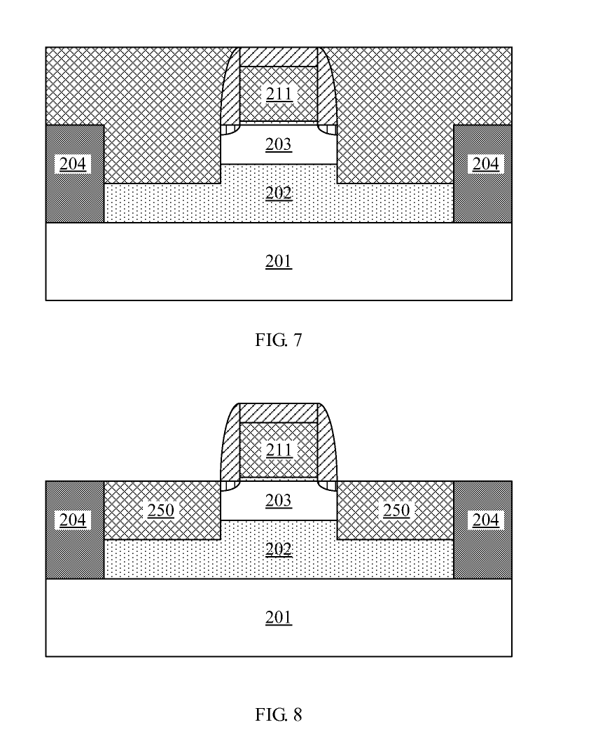

Referring to FIG. 2 and FIG. 7, in step S104, semiconducting materials are filled in the opening 240. The semiconducting materials can be doped polycrystalline silicon or monocrystalline silicon. In the exemplary embodiment, the polycrystalline silicon or monocrystalline silicon are formed by depositing amorphous silicon and annealing. The Doping can also be performed by ion implantation and annealing with a doping concentration of about 10¹⁹−10²¹ cm⁻³. The semiconducting materials can be N-type doped for NMOS and P-type doped for PMOS. The annealing can be performed by rapid thermal annealing, spike annealing, or other suitable methods. After filling the semiconducting materials, Chemical Mechanical Polishing (CMP) can be performed to the semiconducting materials so that the upper surface of the semiconducting materials is flushed with the upper surface of the gate stack structure (The term ‘flushed with’ means the height difference of both is within the allowance of processing error).

As illustrated in FIG. 8, part of the semiconducting materials is removed so that the upper surface of the semiconducting materials is flushed with the lower surface of the gate stack so as to form a source/drain region 250. The semiconducting materials can be removed by wet etching and/or dry etching. In the wet etching process, tetramethyl ammonium hydroxide (TMAH), potassium hydroxide (KOH), or other suitable corrosive solutions may be used. In the dry etching process, carbon hydrides such as sulfur hexafluoride (SF₆), hydrogen bromide (HBr), iodide, hydrogen (HI), chlorine, argon, helium, methane (and chlorinated methane), acetylene, ethylene, or combinations thereof, and/or other suitable materials may be used. The etching can be controlled to stop by etching time so that the upper surface of the semiconducting materials is flushed with the lower surface of the gate stack.

A semiconducting structure is also provided in the present disclosure, as illustrated in FIG. 8. The semiconducting structure comprises an SOI substrate, a gate stack and a source/drain region 250. The SOI substrate comprises, from bottom to top, a base layer 201, a buried insulator layer 202, and a surface active layer 203; the gate stack is located above the surface active layer 203; and the source/drain region 250 is located on both sides of the gate stack, and is extended to the buried insulator layer 202. The semiconducting structure can also comprise spacers located on the sidewalls of the gate stack. The materials for the source/drain region 250 are doped polycrystalline silicon or monocrystalline silicon with a doping concentration of about 10¹⁹−10²¹ cm⁻³. The doping type of the source/drain region 250 is N-type for NMOS and P-type for PMOS. The lower surface of the source/drain region 250 is lower than the upper surface of the buried insulator layer 202 with a height difference in a range of about 100 nm-200 nm. Since the source/drain region extends to the buried insulator layer of the substrate, the source/drain series resistance is reduced while not increasing the parasitic capacitance between the gate and the source/drain.

While the exemplary embodiment and its advantages have been described in detail, it should be understood that various changes, substitutions and modifications can be made to these embodiments without deviating from the spirit of the invention and the scope defined in appended claims. For other examples, those skilled in the art should easily understand that the order of process steps may be changed without deviating from the scope of protection of the present disclosure.

Additionally, the scope of application of the present invention is not limited to the processes, organization, manufacturing, material composition, means, methods and steps described herein for the particular embodiments. From the disclosure of the present invention, people skilled in the art may easily understand that, for the processes, organization, manufacturing, material composition, means, methods or steps that are currently existing or to be developed later, they can be used in accordance with the present invention, to perform substantially the same functions as the embodiments described in the present invention or to achieve substantially the same results. Accordingly, the scope of the appended claims of the present invention comprises these processes, organization, manufacturing, material composition, means, methods or steps.

I/we claim:

1. A method for manufacturing a semiconductor structure, comprising:
a) providing an SOI substrate (200) comprising, from bottom to top, a base layer (201), a buried insulator layer (202), and a surface active layer (203);
b) forming a gate stack on the substrate;
c) removing the surface active layer (203) on both sides of the gate stack and a part of the buried insulator layer (202) to form an opening (240); and
d) filling the opening (240) with semiconductor materials to form a source/drain region (250).

2. The method according to claim 1, wherein in step b), the method further comprises forming spacers (230) on sidewalls of the gate stack.

3. The method according to claim 1, wherein in step c), the surface active layer (203) is etched, and then the buried insulator layer (202) is etched, and the etching stops in the buried insulator layer (202).

4. The method according to claim 1, wherein in step d), the semiconducting materials are doped polycrystalline silicon or monocrystalline silicon with a doping concentration of 10¹⁹−10²¹ cm⁻³.

5. The method according to claim 1, wherein the semiconducting materials are N-type doped for NMOS and P-type doped for PMOS.

6. The method according to claim 4, wherein the polycrystalline silicon or monocrystalline silicon is formed by depositing amorphous silicon and annealing.

7. The method according to claim 6, wherein after the annealing, the method further comprises removing part of the semiconducting materials so that an upper surface of the semiconducting materials is flushed with a lower surface of the gate stack.

8. The method according to claim 7, wherein the part of the semiconducting materials is removed by chemical mechanical polishing and etching, and the etching is stopped by controlling the etching time.

9. A semiconducting structure, comprising an SOI substrate (200), a gate stack and a source/drain region (250), wherein:
the SOI substrate comprises, from bottom to top, a base layer (201), a buried insulator layer (202), and a surface active layer (203);
the gate stack is located above the surface active layer (203); and
the source/drain region is located on both sides of the gate stack, and is extended to the buried insulator layer.

10. The semiconducting structure according to claim 9, further comprising spacers (230), wherein the spacers (230) are located on sidewalls of the gate stack.

11. The semiconducting structure according to claim 9, wherein a lower surface of the source/drain region (250) is lower than an upper surface of the buried insulator layer (202) with a height difference in a range of about 100 nm-200 nm.

12. The semiconducting structure according to claim 9, wherein the material for the source/drain region (250) are doped polycrystalline silicon or monocrystalline silicon with a doping concentration of 10¹⁹−10²¹ cm⁻³.

13. The semiconducting structure according to claim 9, wherein the source/drain region (250) is N-type doped for NMOS and P-type doped for PMOS.
